(19) United States
(12) Patent Application Publication
(10) Pub. No.: US 2026/0180526 A1
(43) Pub. Date: Jun. 25, 2026

(54) SECOND HARMONIC (HD2) AND DISTORTION COMPENSATION FOR A POWER AMPLIFIER

(71) Applicant: NXP USA, Inc., AUSTIN, TX (US)

(72) Inventors: Sai-Wang Tam, Sunnyvale, CA (US); Mohammadreza Abbasi, State College, PA (US); Cheng Chen, Cupertino, CA (US); Ovidiu Carnu, Scotts Valley, CA (US); Juan Xie, Cupertino, CA (US); Alden C Wong, Cupertino, CA (US)

(21) Appl. No.: 18/988,308

(22) Filed: Dec. 19, 2024

(51) Int. Cl. H03F 3/24; H03F 1/02

(52) U.S. Cl. CPC H03F 3/245; H03F 1/0222; H03F 2200/105; H03F 2200/451

(57) ABSTRACT

Embodiments of a compensation circuit for a power amplifier (PA) and a method of PA compensation are disclosed. In an embodiment, a compensation circuit for a power amplifier (PA) includes an envelope detector configured to measure an input power of the PA and a bias offset generator configured to apply a voltage offset in response to the input power of the PA to generate bias voltages that are applied to back gates of transistor devices of the PA for distortion compensation and second harmonic (HD2) compensation of the PA.

### BACKGROUND

Second harmonic (HD2) emission from a power amplifier (PA) may violate Federal Communications Commission (FCC) emission limits. In addition, a PA may experience gain compression and/or face gain expansion. For example, at 60 gigahertz (GHz), a PA may experience gain compression, which leads to AM-AM distortion. At 2.4 GHz, a PA may not only face gain compression but also face gain expansion, triggering a dual challenge that further complicates linearity.

### SUMMARY

Embodiments of a compensation circuit for a power amplifier (PA) and a method of PA compensation are disclosed. In an embodiment, a compensation circuit for a power amplifier (PA) includes an envelope detector configured to measure an input power of the PA and a bias offset generator configured to apply a voltage offset in response to the input power of the PA to generate bias voltages that are applied to back gates of transistor devices of the PA for distortion compensation and second harmonic (HD2) compensation of the PA. Other embodiments are also disclosed.

In an embodiment, the envelope detector is further configured to measure the input power of the PA to generate a bias voltage, and the bias offset generator is further configured to apply the voltage offset to the bias voltage to generate a differential pair of bias voltages.

In an embodiment, the envelope detector is operably connected to input terminals of the PA to sense an input voltage of the PA.

In an embodiment, the envelope detector includes a first passive mixer with a first gain and a second passive mixer with a second gain.

In an embodiment, the envelope detector further includes a transimpedance amplifier (TIA) configured to convert a sum of output currents of the first and second passive mixers into an output voltage.

In an embodiment, the bias offset generator includes a voltage adder circuit configured to add the voltage offset to the output voltage to generate a first bias voltage and a voltage subtractor circuit configured to subtract the voltage offset from the output voltage to generate a second bias voltage.

In an embodiment, the PA includes a sub-6 gigahertz (GHz) PA.

In an embodiment, the sub-6 GHz PA includes cascode devices and transistor devices with back gates operably connected to the cascode devices.

In an embodiment, the transistor devices with the back gates comprise segments of transistor devices and multiplexers.

In an embodiment, the PA includes a millimeter wave (mmWave) PA.

In an embodiment, the mmWave PA includes capacitors and transistor devices with back gates operably connected to the capacitors.

In an embodiment, a compensation circuit for a sub-6 gigahertz (GHz) PA includes an envelope detector configured to measure an input power of the PA to generate a bias voltage and a bias offset generator configured to apply a voltage offset to the bias voltage to generate a differential pair of bias voltages that is applied to back gates of transistor devices of the PA for distortion compensation and second harmonic (HD2) compensation of the PA.

In an embodiment, the sub-6 GHZ PA includes cascode devices and transistor devices with back gates operably connected to the cascode devices.

In an embodiment, the transistor devices with the back gates comprise segments of transistor devices and multiplexers.

In an embodiment, the envelope detector is operably connected to input terminals of the sub-6 GHZ PA to sense an input voltage of the sub-6 GHZ PA.

In an embodiment, the envelope detector includes a first passive mixer with a first gain and a second passive mixer with a second gain.

In an embodiment, the envelope detector further includes a transimpedance amplifier (TIA) configured to convert a sum of output currents of the first and second passive mixers into an output voltage.

In an embodiment, the bias offset generator includes a voltage adder circuit configured to add the voltage offset to the output voltage to generate a first bias voltage and a voltage subtractor circuit configured to subtract the voltage offset from the output voltage to generate a second bias voltage.

In an embodiment, a method for power amplifier (PA) compensation involves using an envelope detector, measuring an input power of a PA; and using a bias offset generator, applying a voltage offset in response to the input power of the PA to generate bias voltages that are applied to back gates of transistor devices of the PA for distortion compensation and second harmonic (HD2) compensation of the PA.

In an embodiment, using the envelope detector, measuring the input power of the PA includes using the envelope detector, measuring the input power of the PA to generate a bias voltage, and using the bias offset generator, applying the voltage offset in response to the input power of the PA to generate the bias voltages includes using the bias offset generator, applying the voltage offset to the bias voltage to generate a differential pair of bias voltages.

Other aspects in accordance with the invention will become apparent from the following detailed description, taken in conjunction with the accompanying drawings, illustrated by way of example of the principles of the invention.

### BRIEF DESCRIPTION OF THE DRAWINGS

FIG. 1 depicts an electronic device in accordance with an embodiment of the invention.

FIG. 2 depicts an electronic device in accordance with an embodiment of the invention.

FIG. 3 depicts a plot of PA output power versus back gate (BG) bias offset of the electronic device depicted in FIG. 2.

FIG. 4 depicts a plot of bias voltage versus PA input power of the electronic device depicted in FIG. 2.

FIG. 5 depicts a plot of PA gain versus PA input power of the electronic device depicted in FIG. 2.

FIG. 6 depicts a PA in accordance with an embodiment of the invention.

FIG. 7 depicts a PA with multiple segments in accordance with an embodiment of the invention.

FIG. 8 depicts a PA with multiple segments for HD2 compensation and multiple segments for AM-AM compensation in accordance with an embodiment of the invention.

FIG. 9 depicts an electronic device in accordance with an embodiment of the invention.

FIG. 10 depicts a plot of PA output power versus BG bias offset of the electronic device depicted in FIG. 9.

FIG. 11 depicts a plot of PA output power versus BG bias offset under different gate-drain voltages of the electronic device depicted in FIG. 9.

FIG. 12 depicts a plot of bias voltage versus PA input power of the electronic device depicted in FIG. 9.

FIG. 13 depicts a plot of PA gain versus PA input power of the electronic device depicted in FIG. 9.

FIG. 14 depicts a transistor device in accordance with an embodiment of the invention.

FIG. 15 depicts a schematic diagram of the transistor device depicted in FIG. 14.

FIG. 16 depicts a plot of the threshold voltage and transconductance (Gm) of the transistor device depicted in FIG. 14 versus the back gate bias voltage of the transistor device depicted in FIG. 14.

FIG. 17 is a process flow diagram of a method for PA compensation in accordance with an embodiment of the invention.

Throughout the description, similar reference numbers may be used to identify similar elements.

### DETAILED DESCRIPTION

It will be readily understood that the components of the embodiments as generally described herein and illustrated in the appended figures could be arranged and designed in a wide variety of different configurations. Thus, the following more detailed description of various embodiments, as represented in the figures, is not intended to limit the scope of the present disclosure, but is merely representative of various embodiments. While the various aspects of the embodiments are presented in drawings, the drawings are not necessarily drawn to scale unless specifically indicated.

The present invention may be embodied in other specific forms without departing from its spirit or essential characteristics. The described embodiments are to be considered in all respects only as illustrative and not restrictive. The scope of the invention is, therefore, indicated by the appended claims rather than by this detailed description. All changes which come within the meaning and range of equivalency of the claims are to be embraced within their scope.

Reference throughout this specification to features, advantages, or similar language does not imply that all of the features and advantages that may be realized with the present invention should be or are in any single embodiment of the invention. Rather, language referring to the features and advantages is understood to mean that a specific feature, advantage, or characteristic described in connection with an embodiment is included in at least one embodiment of the present invention. Thus, discussions of the features and advantages, and similar language, throughout this specification may, but do not necessarily, refer to the same embodiment.

Furthermore, the described features, advantages, and characteristics of the invention may be combined in any suitable manner in one or more embodiments. One skilled in the relevant art will recognize, in light of the description herein, that the invention can be practiced without one or more of the specific features or advantages of a particular embodiment. In other instances, additional features and advantages may be recognized in certain embodiments that may not be present in all embodiments of the invention.

Reference throughout this specification to “one embodiment”, “an embodiment”, or similar language means that a particular feature, structure, or characteristic described in connection with the indicated embodiment is included in at least one embodiment of the present invention. Thus, the phrases “in one embodiment”, “in an embodiment”, and similar language throughout this specification may, but do not necessarily, all refer to the same embodiment.

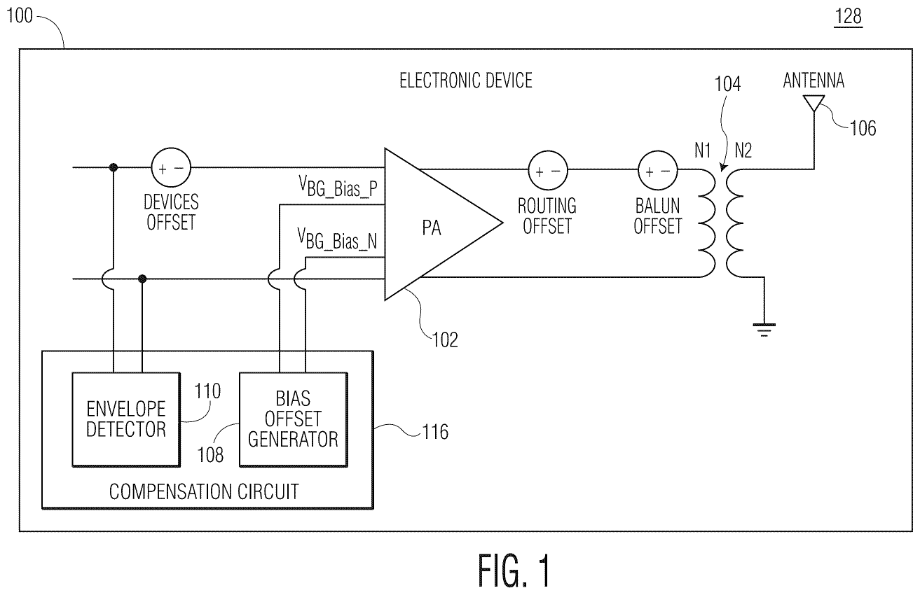

FIG. 1 depicts an electronic device 100 in accordance with an embodiment of the invention. In the embodiment depicted in FIG. 1, the electronic device 100 includes a power amplifier (PA) 102, a transformer 104, an antenna 106, and a compensation circuit 116 that includes a bias offset generator 108 and an envelope detector 110. The electronic device 100 can be used in various applications, such as consumer or enterprise applications, medical applications, computer applications, and/or industrial applications. In some embodiments, the electronic device 100 is a transmitter circuit, for example, a wireless transmitter circuit. Although the depicted electronic device 100 is shown in FIG. 1 with certain components and described with certain functionality herein, other embodiments of the electronic device 100 may include fewer or more components to implement the same, less, or more functionality. In addition, although the electronic device 100 is shown in FIG. 1 as being connected in a certain topology, the network topology of the electronic device 100 is not limited to the topology shown in FIG. 1.

In the embodiment depicted in FIG. 1, the transformer 104 is operably connected to the PA 102 and to the antenna 106 and has a transformer ratio of N1/N2, where N1, N2 are positive integers. The transformer 104 may be connected to a fixed voltage, such as the ground (zero volt). In some embodiments, the transformer 104 is a Balun transformer.

Second harmonic (HD2) emission from the PA 102 can violate FCC emission limits. For example, Complementary Metal-Oxide-Semiconductor (CMOS) power amplifiers typically have high HD2 emission. The HD2 tone can be sufficiently large that violates the FCC limitation, which is-41 decibel milliwatts/megahertz (dBm/MHz). In conventional implementations, an external low pass filter may be required to filter out HD2, which can increase component costs, circuit size, and/or power consumption. In addition, the PA 102 may experience gain compression and/or face gain expansion. For example, at 60 gigahertz (GHz), the PA can experience gain compression, which leads to AM-AM distortion, which is the difference between the supply voltage and the envelope of the radio frequency (RF) output voltage that can be caused by a nonlinear relationship between the supply voltage and the envelope of the RF output signal. At 2.4 GHz, the PA may not only face gain compression but also face gain expansion, triggering a dual challenge that further complicates linearity.

Conventional implementations, such as asymmetric Balun capacitors for HD2 compensation and adaptive feed forward AM-AM Bias circuits, have various disadvantages. For example, asymmetric Balun capacitors for HD2 compensation are exactly located at the signal path, which can degrade linearity and efficiency. In addition, there are device stresses due to high signal swing and difficult trade-off of between asymmetric Balun capacitors resolution and power loss for the switches while occupying large substrate area. In another example, adaptive feed forward AM-AM bias circuits are exactly located at the signal Path. Modulate in Common only suite with AM-AM compensation (No HD2 Compensation). There are memory effect with high bandwidth envelope and no segmentations for the Adaptive Feed Forward AM-AM Bias. It can be difficult to drive large gm devices.

Four major mechanisms of HD2 in the PA 102 include duty cycle mis-match of the Narrow Band (NB) such as Bluetooth or Institute of Electrical and Electronics Engineers (IEEE) 15.4 PA input (random error), Push-Push rectifier effect at High input (Systemic & Output power dependent), Supply domain crossing buffer (Systemic & Output power dependent), and PA devices, output routing and balun mis-match (systemic). HD2 in the PA 102 can be expressed as:

$$HD 2 \approx {gm}_{HD 2} \cdot {V}_{+}^{2} - ( {gm}_{HD 2} + Δ {gm}_{HD 2} ) \cdot {V}_{-}^{2} \approx Δ {gm}_{HD 2} \cdot {V}_{diff}^{2} , \qquad ( 1 )$$

where HD2 represents HD2 in the PA 102, gm_{HD2} represents transconductance of the 2nd harmonic, Δgm_{HD2} represents change of the transconductance in 2nd harmonic, V+ represents Vin_positive of the PA differential PA, V− represents Vin_negative of the PA differential input, V_{diff}=V+−V−, which is the differential input. Minimizing system offset can reduce HD2.

In the embodiment depicted in FIG. 1, the compensation circuit 116, which includes the bias offset generator 108 and the envelope detector 110, is used for on-chip HD2 and AM-AM distortion compensation of the PA 102. Using the compensation circuit 116, which includes the bias offset generator 108 and the envelope detector 110, the systemic offset of the PA 102, such as routing, balun and devices mismatch, can be effectively canceled out by adjusting offset voltages between, for example, back gates of semiconductor devices in the PA 102. In addition, the AM-AM distortion is compensated with adaptive biasing through, for example, back gates of semiconductor devices in the PA 102. Subsequently, the corresponding limitation of the HD2 emission and AM-AM distortion in the electronic device 100 can be eliminated, which enables the possibility of the high-power transmitters without violating the spectrum mask due to out-of-band HD2 emission and compensating AM-AM cancelation at the same time through, for example, back gates of semiconductor devices in the PA 102.

In the embodiment depicted in FIG. 1, the bias offset generator 108 is configured to generate bias voltages that are applied to the PA 102. The bias offset generator 108 may be implemented in hardware (e.g., circuits), software, firmware, or a combination thereof. In the embodiment depicted in FIG. 1, the envelope detector 110 is configured to perform envelope detection. The envelope detector 110 may be fully or partially implemented as an integrated circuit (IC) device. In some embodiments, the bias offset generator 108 and the envelope detector 110 are located in the same substrate and are implemented as one IC device (e.g., a system on chip (SOC)). In some embodiments, the bias offset generator 108 and the envelope detector 110 are located in separate substrates and are implemented as separate IC devices. Using the bias offset generator 108 and the envelope detector 110, adaptive biasing can be implemented through back gates of semiconductor devices, such as, silicon on insulator (SOI) devices of the PA 102. For a 60 GHz PA, adaptive biasing helps to mitigate gain compression. For a 2.4 GHz PA, adaptive biasing is used to address both gain compression and expansion, which reduces the AM-AM distortion.

In accordance with an embodiment of the invention, the envelope detector 110 is configured to measure an input power of the PA 102 and the bias offset generator 108 is configured to apply a voltage offset in response to the input power of the PA to generate bias voltages that are applied to back gates of transistor devices of the PA for distortion compensation and second harmonic (HD2) compensation of the PA. In some embodiments, the envelope detector 110 is further configured to measure the input power of the PA 102 to generate a bias voltage, and the bias offset generator 108 is further configured to apply the voltage offset to the bias voltage to generate a differential pair of bias voltages. In some embodiments, the envelope detector 110 is operably connected to input terminals of the PA 102 to sense an input voltage of the PA 102. In some embodiments, the envelope detector 110 includes a first passive mixer with a first gain and a second passive mixer with a second gain. In some embodiments, the envelope detector 110 further includes a transimpedance amplifier (TIA) configured to convert a sum of output currents of the first and second passive mixers into an output voltage. In some embodiments, the bias offset generator 108 includes a voltage adder circuit configured to add the voltage offset to the output voltage to generate a first bias voltage and a voltage subtractor circuit configured to subtract the voltage offset from the output voltage to generate a second bias voltage. In some embodiments, the PA 102 includes a sub-6 gigahertz (GHz) PA. In some embodiments, the sub-6 GHZ PA includes cascode devices and transistor devices with back gates operably connected to the cascode devices. In some embodiments, the transistor devices with the back gates includes segments of transistor devices and multiplexers. In some embodiments, the PA 102 includes a millimeter wave (mmWave) PA. In some embodiments, the mmWave PA includes capacitors and transistor devices with back gates operably connected to the capacitors.

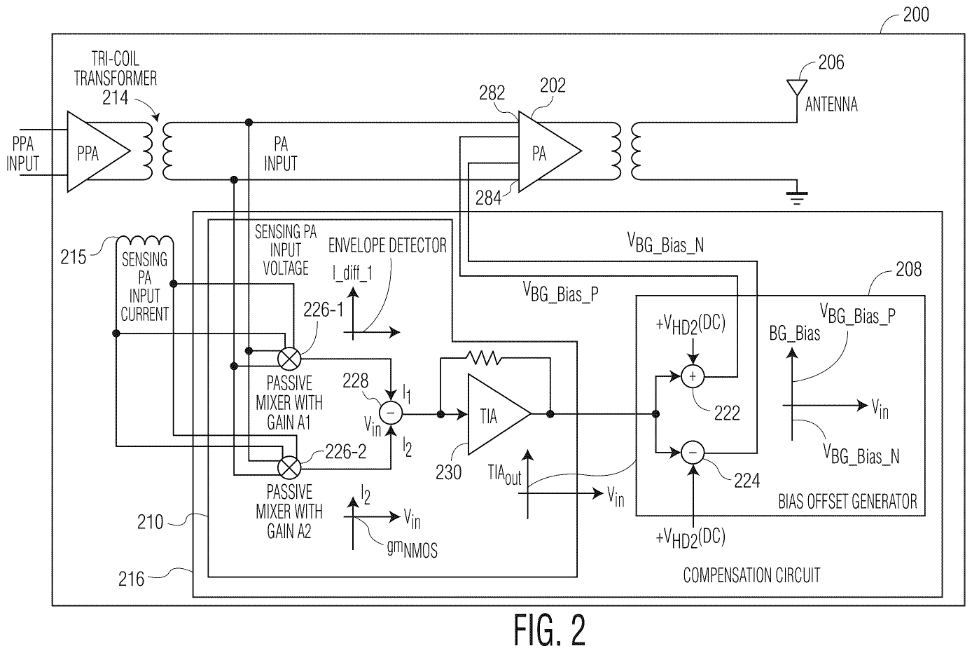

FIG. 2 depicts an electronic device 200 in accordance with an embodiment of the invention. The electronic device 200 can be used for sub-6 GHz adaptative back gate bias for HD2 and AM-AM cancelation. The electronic device 200 depicted in FIG. 2 is an embodiment of the electronic device 100 depicted in FIG. 1. However, the electronic device 100 depicted in FIG. 1 is not limited to the embodiment depicted in FIG. 2. In the embodiment depicted in FIG. 2, the electronic device 200 includes a power amplifier (PA) 202, a transformer 204, an antenna 206, a compensation circuit 216 that includes a bias offset generator 208 and an envelope detector 210, a Pre-PA (PPA) 212, and a tri-coil transformer 214. The PA 202 may include N segments of PA gm input devices with BG bias inputs, where N is a positive integer that is larger than one. The PA 202, the transformer 204, the antenna 206, the compensation circuit 216, the bias offset generator 208, and the envelope detector 210 depicted in FIG. 2 are embodiments of the PA 102, the transformer 104, the antenna 106, the compensation circuit 116, the bias offset generator 108, and the envelope detector 110 depicted in FIG. 1. However, the PA 102, the transformer 104, the antenna 106, the compensation circuit 116, the bias offset generator 108, and the envelope detector 110 depicted in FIG. 1 are not limited to the embodiments depicted in FIG. 2. In some embodiments, the electronic device 200 is a transmitter circuit, for example, a wireless transmitter circuit. Although the depicted electronic device 200 is shown in FIG. 2 with certain components and described with certain functionality herein, other embodiments of the electronic device 200 may include fewer or more components to implement the same, less, or more functionality. In addition, although the electronic device 200 is shown in FIG. 2 as being connected in a certain topology, the network topology of the electronic device 200 is not limited to the topology shown in FIG. 2.

In the embodiment depicted in FIG. 2, the transformer 204 is operably connected to the PA 202 and to the antenna 206. The transformer 204 may be connected to a fixed voltage, such as the ground (zero volt). In some embodiments, the transformer 204 is a Balun transformer.

In the embodiment depicted in FIG. 2, the compensation circuit 216, which includes the bias offset generator 208 and the envelope detector 210, is used for on-chip HD2 and AM-AM distortion compensation of the PA 202. Using the compensation circuit 216 that includes the bias offset generator 208 and the envelope detector 210, the systemic offset of the PA 202, such as routing, balun and devices mismatch, can be effectively canceled out by adjusting offset voltages between back gates of semiconductor devices in the PA 202. In addition, the AM-AM distortion is compensated with adaptive biasing through back gates of semiconductor devices in the PA 202. Subsequently, the corresponding limitation of the HD2 emission and AM-AM distortion in the electronic device 200 can be eliminated, which enables the possibility of the high-power transmitters without violating the spectrum mask due to out-of-band HD2 emission and compensating AM-AM cancelation at the same time through back gates of semiconductor devices in the PA 202. The bias offset generator 208 and/or the envelope detector 210 may be fully or partially implemented as an IC device. In some embodiments, the bias offset generator 208 and the envelope detector 210 are located in the same substrate and are implemented as one IC device (e.g., a system on chip (SOC)). In some embodiments, the bias offset generator 208 and the envelope detector 210 are located in separate substrates and are implemented as separate IC devices. Using the bias offset generator 208 and the envelope detector 210, adaptive biasing can be implemented through back gates of semiconductor devices, such as, silicon on insulator (SOI) devices of the PA 202. For a 2.4 GHz PA, adaptive biasing is used to address both gain compression and expansion, which reduces the AM-AM distortion.

In the embodiment depicted in FIG. 2, the bias offset generator 208 is configured to generate differential bias voltages V_{BG_BIAS_P}, V_{BG_BIAS_N} that are applied to the back gate of the PA 202. In the embodiment depicted in FIG. 2, the bias offset generator 208 includes a voltage adder circuit 222 and a voltage subtractor circuit 224.

In the embodiment depicted in FIG. 2, the envelope detector 210 is configured to perform envelope detection. In the embodiment depicted in FIG. 2, the envelope detector 210 includes a first passive mixer 226-1 with gain A1, a second passive mixer 226-2 with gain A2, a subtractor circuit 228, and a transimpedance amplifier (TIA) 230.

In the embodiment depicted in FIG. 2, the tri-coil transformer 214 includes a third coil 215 configured to sense the input current for the PA 202. Each of the first passive mixer 226-1 and the second passive mixer 226-2 is operably connected to the third coil 215 and to PA input terminals 282, 284 to sense the PA input current and to sense the PA input voltage, respectively. Each of the first passive mixer 226-1 and the second passive mixer 226-2 may measure PA input power by I_PA_IN×V_PA_IN. In the embodiment depicted in FIG. 2, the first passive mixer 226-1 with gain A1 is used for gain compression, while the second passive mixer 226-2 with gain A2 is used for gain expansion. The subtractor circuit 228 and the TIA 230 are used to convert the sum of output currents of two passive mixers 226-1, 226-2 into an output voltage. The bias offset generator 208 generates two separate static DC offsets for HD2 compensation based on the output voltage from the TIA 230. In the embodiment depicted in FIG. 2, the voltage adder circuit 222 adds V_{HD2}(DC) to the output voltage TIAₒᵤₜ of the TIA 230 and the voltage subtractor circuit 224 subtracts V_{HD2}(DC) from the output voltage TIAₒᵤₜ of the TIA 230 to generate the differential bias voltages, V_{BG_Bias_P}, V_{BG_Bias_N}, respectively. For example, the bias voltages, V_{BG_Bias_P}, V_{BG_Bias_N}, are applied to back gates of the transistors of the PA 202. In some embodiments, the bias voltages, V_{BG_Bias_P}, V_{BG_Bias_N}, are expressed as:

$${V}_{BG \_ Bias \_ P} = + {V}_{HD 2} ( DC ) + {V}_{AM - AM} ( CM Dynamic ) , \qquad ( 2 )$$

$${V}_{BG \_ Bias \_N} = - {V}_{HD 2} ( DC ) + {V}_{AM - AM} ( CM Dynamic ) , \qquad ( 3 )$$

where V_{HD2}(DC) represents static differential dc offset for HD2 compensation, V_{AM-AM} (CM Dynamic) represents Dynamic Common Mode BG Bias based on PA input Envelope for AM-AM Compensation.

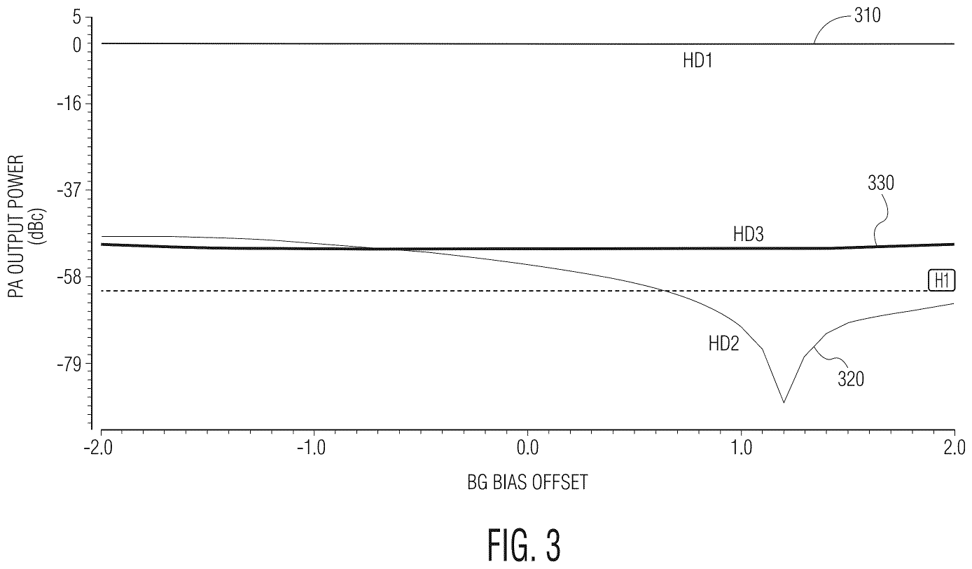

FIG. 3 depicts a plot of PA output power versus BG bias offset of the electronic device 200 depicted in FIG. 2. As depicted in FIG. 3, the curve 310 represents first harmonic (HD1), the curve 320 represents second harmonic (HD2), and the curve 330 represents third harmonic (HD3). As depicted in FIG. 3, HD2 reduction or cancelation can be achieved using static BG bias offset.

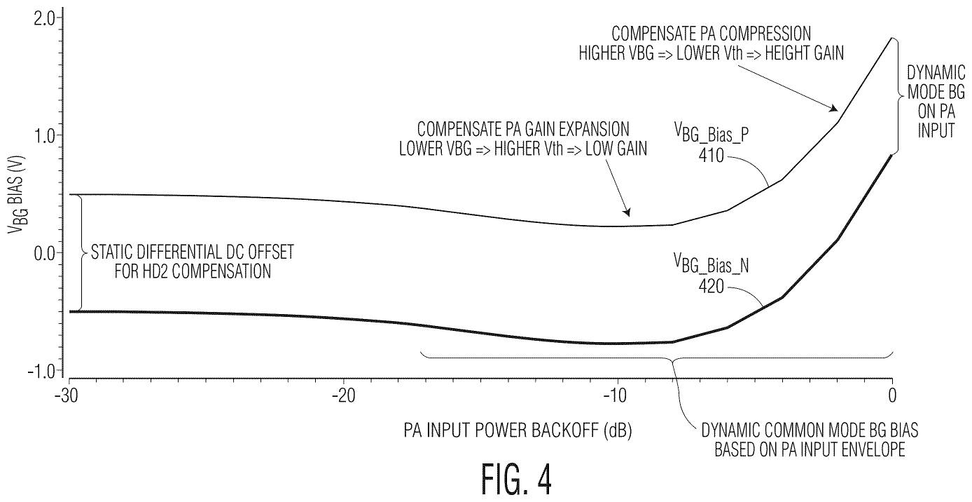

FIG. 4 depicts a plot of bias voltage versus PA input power (back off) of the electronic device 200 depicted in FIG. 2. As depicted in FIG. 4, the curve 410 represents the bias voltage V_{BG_Bias_P}, while the curve 420 represents the bias voltage V_{BG_Bias_N}. In low PA input power, the difference between the bias voltages, V_{BG_Bias_P}, V_{BG_Bias_N} is the static Differential DC Offset for HD2 compensation, in high low PA input power, the difference between the bias voltages, V_{BG_Bias_P}, V_{BG_Bias_N} is the dynamic common mode BG Bias based on PA input envelope. For lower V_{BG}, PA gain expansion can be compensated (Lower V_{BG}=>Higher Vth=>Low Gain). For higher V_{BG}, PA gain compression can be compensated (Higher V_{BG}=>Lower Vth=>Hight Gain).

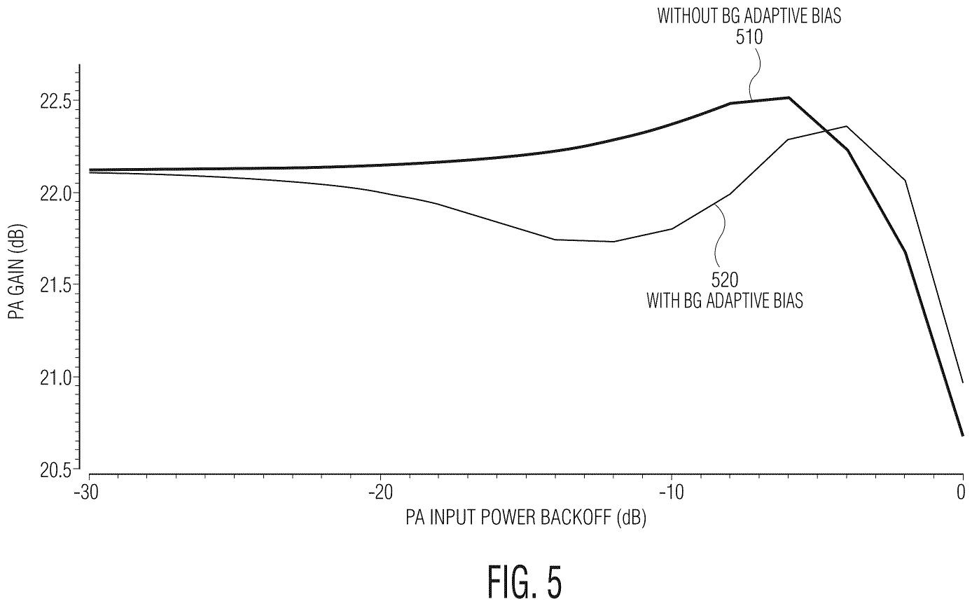

FIG. 5 depicts a plot of PA gain versus PA input power (back off) of the electronic device 200 depicted in FIG. 2. As depicted in FIG. 5, the curve 510 represents PA gain without BG adaptive Bias, while the curve 520 represents PA gain with BG adaptive Bias.

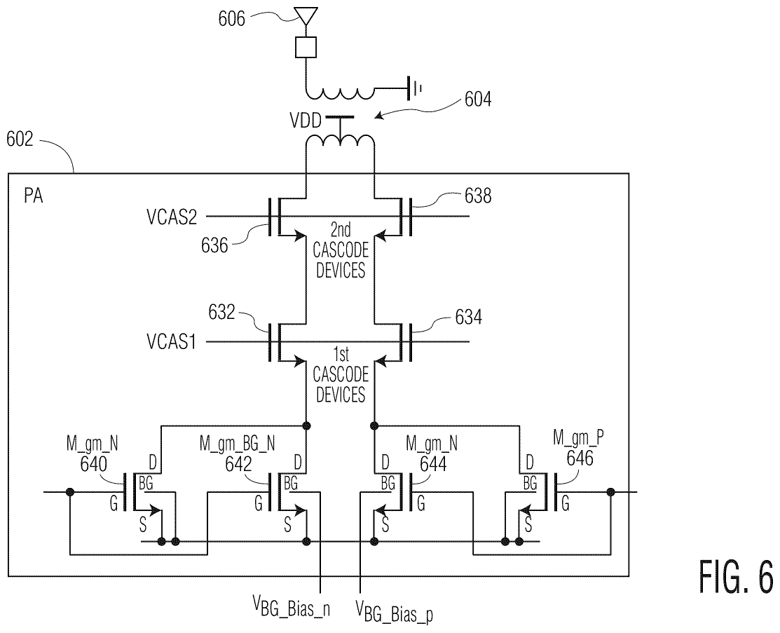

FIG. 6 depicts a PA 602 in accordance with an embodiment of the invention. In the embodiment depicted in FIG. 6, the PA 602 is a sub-6 GHZ PA that faces gain compression and gain expansion and sub-6 GHZ adaptative back gate bias for HD2 and AM-AM cancelation can be implemented for the PA 602. The PA 602 depicted in FIG. 6 is an embodiment of the PA 202 depicted in FIG. 2. However, the PA 202 depicted in FIG. 2 is not limited to the embodiment depicted in FIG. 6. In the embodiment depicted in FIG. 6, the PA 602 includes first cascode transistor devices 632, 634, second cascode transistor devices 636, 638 that are operably connected to a transformer 604, and transistor devices 640, 642, 644, 646 with back gates BG. In the embodiment depicted in FIG. 6, the transformer 604 is operably connected to the PA 602 and to an antenna 606. The transformer 604 may be connected to a fixed voltage, such as the ground (zero volt). In some embodiments, the transformer 604 is a Balun transformer. Although the depicted PA 602 is shown in FIG. 6 with certain components and described with certain functionality herein, other embodiments of the PA 602 may include fewer or more components to implement the same, less, or more functionality. In addition, although the PA 602 is shown in FIG. 6 as being connected in a certain topology, the network topology of the PA 602 is not limited to the topology shown in FIG. 6.

In the embodiment depicted in FIG. 6, the first cascode transistor devices 632, 634 and the second cascode transistor devices 636, 638 are N-type Metal-Oxide-Semiconductor (NMOS) devices. In the embodiment depicted in FIG. 6, the transistor devices 640, 642, 644, 646 are NMOS devices with back gates BG. Specifically, a bias voltage V_{BG_Bias_N}, which may be generated by the bias offer generator 208 depicted in FIG. 2, is applied to the back gate BG of the transistor device 642 (also referred to as M_gm_BG_N), while a bias voltage V_{BG_Bias_P}, which may be generated by the bias offer generator 208 depicted in FIG. 2, is applied to the back gate BG of the transistor device 644 (also referred to as M_gm_BG_P). The gate terminal G of the transistor device 642 is connected to the gate terminal G of the transistor device 640 (also referred to as M_gm_N), the source terminal S of the transistor device 642 is connected to the source terminal S of the transistor device 640, and the drain terminal D of the transistor device 642 is connected to the drain terminal D of the transistor device 640 and the cascode device 632. The gate terminal G of the transistor device 644 is connected to the gate terminal G of the transistor device 646 (also referred to as M_gm_P), the source terminal S of the transistor device 644 is connected to the source terminal S of the transistor device 646, and the drain terminal D of the transistor device 644 is connected to the drain terminal D of the transistor device 646 and the cascode device 634. In the embodiment depicted in FIG. 6, the BG bias voltages V_{BG_Bias_P}, V_{BG_Bias_N} are used to adjust both HD2 (differential Mode) and AM-AM (common mode (CM)).

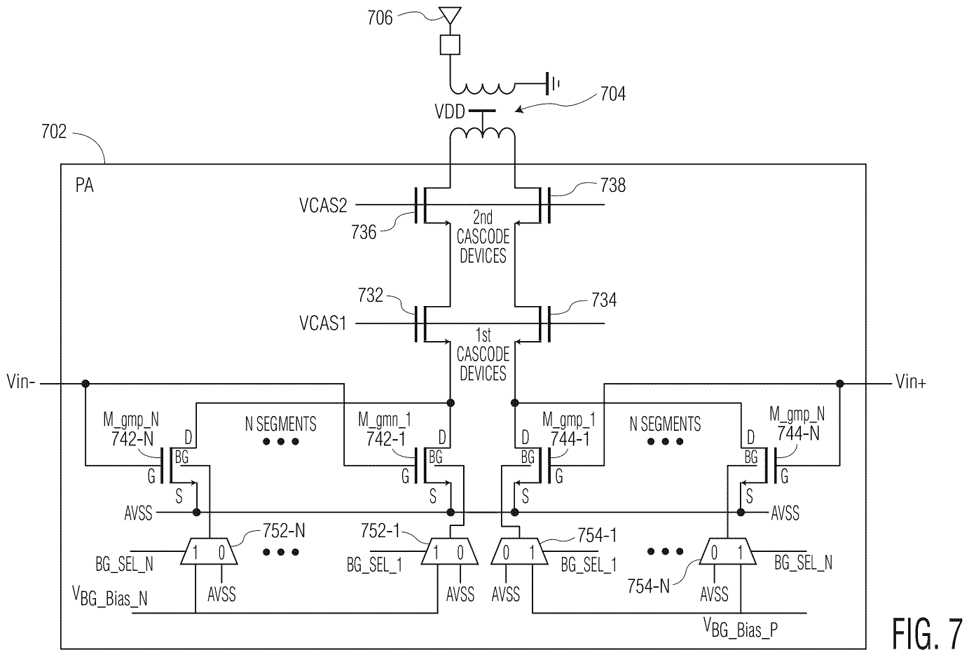

FIG. 7 depicts a PA 702 with multiple segments in accordance with an embodiment of the invention. In the embodiment depicted in FIG. 7, the PA 702 is a sub-6 GHZ PA that faces gain compression and gain expansion and sub-6 GHz adaptative back gate bias for HD2 and AM-AM cancelation can be implemented for the PA 702. The PA 702 depicted in FIG. 7 is an embodiment of the PA 202 depicted in FIG. 2. However, the PA 202 depicted in FIG. 2 is not limited to the embodiment depicted in FIG. 7. In the embodiment depicted in FIG. 7, the PA 702 includes first cascode transistor devices 732, 734, second cascode transistor devices 736, 738 that are operably connected to a transformer 704, transistor devices 742-1, . . . , 742-N, 744-1, . . . , 744-N with back gates BG (N is a positive integer that is greater than one), and multiplexers 752-1, . . . , 752-N, 754-1, . . . , 754-N. In the embodiment depicted in FIG. 7, the transformer 704 is operably connected to the PA 702 and to an antenna 706. The transformer 704 may be connected to a fixed voltage, such as the ground (zero volt). In some embodiments, the transformer 704 is a Balun transformer. Although the depicted PA 702 is shown in FIG. 7 with certain components and described with certain functionality herein, other embodiments of the PA 702 may include fewer or more components to implement the same, less, or more functionality. In addition, although the PA 702 is shown in FIG. 7 as being connected in a certain topology, the network topology of the PA 702 is not limited to the topology shown in FIG. 7.

In the embodiment depicted in FIG. 7, the first cascode transistor devices 732, 734 and the second cascode transistor devices 736, 738 are NMOS devices. In the embodiment depicted in FIG. 7, the transistor devices 742-1, . . . , 742-N, 744-1, . . . , 744-N are NMOS devices with back gates BG. Specifically, a bias voltage V_{BG_Bias_N}, which may be generated by the bias offer generator 208 depicted in FIG. 2, is applied to the back gates BG of the transistor devices 742-1, . . . , 742-N (also referred to as M_gmn_1, . . . , M_gmn_N) through the multiplexers 752-1, . . . , 752-N, while a bias voltage V_{BG_Bias_P}, which may be generated by the bias offer generator 208 depicted in FIG. 2, is applied to the back gates BG of the transistor devices 744-1, . . . , 744-N (also referred to as M_gmp_1, . . . , M_gmp_N) through the multiplexers 754-1, . . . , 754-N. The gate terminal G of the transistor device 742-1 is connected to the gate terminal G of the transistor device 742-N and an input voltage V_{in-,} the source terminal S of the transistor device 742-1 is connected to the source terminal S of the transistor device 742-N, and the drain terminal D of the transistor device 742-1 is connected to the drain terminal D of the transistor device 742-N and the cascode device 732. The gate terminal G of the transistor device 744-1 is connected to the gate terminal G of the transistor device 744-N and an input voltage Vᵢₙ₊, the source terminal S of the transistor device 744-1 is connected to the source terminal S of the transistor device 744-N, and the drain terminal D of the transistor device 744-1 is connected to the drain terminal D of the transistor device 744-N and the cascode device 734. In the embodiment depicted in FIG. 7, segmentation on BG bias voltages V_{BG_Bias_P}, V_{BG_Bias_N} are used to adjust both HD2 (differential Mode) and AM-AM (CM).

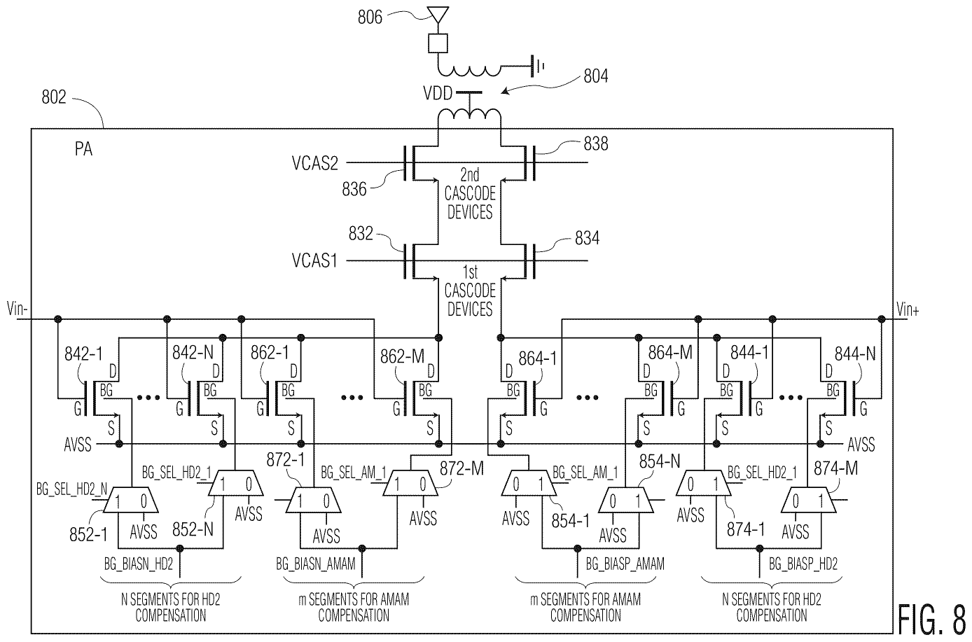

FIG. 8 depicts a PA 802 with multiple segments for HD2 compensation and multiple segments for AM-AM compensation in accordance with an embodiment of the invention. In the embodiment depicted in FIG. 8, the PA 802 is a sub-6 GHZ PA that faces gain compression and gain expansion and sub-6 GHZ adaptative back gate bias for HD2 and AM-AM cancelation can be implemented for the PA 802. The PA 802 depicted in FIG. 8 is an embodiment of the PA 202 depicted in FIG. 2. However, the PA 202 depicted in FIG. 2 is not limited to the embodiment depicted in FIG. 8. In the embodiment depicted in FIG. 8, the PA 802 includes first cascode transistor devices 832, 834, second cascode transistor devices 836, 838 that are operably connected to a transformer 804, transistor devices 842-1, . . . , 842-N, 844-1, . . . , 844-N, 862-1, . . . , 862-M, 864-1, . . . , 864-M with back gates BG (each of N and M is a positive integer that is greater than one), and multiplexers 852-1, . . . , 852-N, 854-1, . . . , 854-N, 872-1, . . . , 872-M, 874-1, . . . , 874-M. In the embodiment depicted in FIG. 8, the transformer 804 is operably connected to the PA 802 and to an antenna 806. The transformer 804 may be connected to a fixed voltage, such as the ground (zero volt). In some embodiments, the transformer 804 is a Balun transformer. Although the depicted PA 802 is shown in FIG. 8 with certain components and described with certain functionality herein, other embodiments of the PA 802 may include fewer or more components to implement the same, less, or more functionality. In addition, although the PA 802 is shown in FIG. 8 as being connected in a certain topology, the network topology of the PA 802 is not limited to the topology shown in FIG. 8.

In the embodiment depicted in FIG. 8, the first cascode transistor devices 832, 834 and the second cascode transistor devices 836, 838 are NMOS devices. In the embodiment depicted in FIG. 8, the transistor devices 842-1, . . . , 842-N, 844-1, . . . , 844-N, 862-1, . . . , 862-M, 864-1, . . . , 864-M are NMOS devices with back gates BG. Specifically, a bias voltage V_{BG_BIASN_HD2} for HD2 compensation, which may be generated by the bias offer generator 208 depicted in FIG. 2, is applied to the back gates BG of the transistor devices 842-1, . . . , 842-N through the multiplexers 852-1, . . . , 852-N, while a bias voltage V_{BG_BIASP_HD2} for HD2 compensation, which may be generated by the bias offer generator 208 depicted in FIG. 2, is applied to the back gates BG of the transistor devices 844-1, . . . , 844-N through the multiplexers 854-1, . . . , 854-N. The gate terminal G of the transistor device 842-1 is connected to the gate terminal G of the transistor device 842-N and an input voltage Vᵢₙ₋, the source terminal S of the transistor device 842-1 is connected to the source terminal S of the transistor device 842-N, and the drain terminal D of the transistor device 842-1 is connected to the drain terminal D of the transistor device 842-N and the cascode device 832. The gate terminal G of the transistor device 844-1 is connected to the gate terminal G of the transistor device 844-N and an input voltage Vᵢₙ₊, the source terminal S of the transistor device 844-1 is connected to the source terminal S of the transistor device 844-N, and the drain terminal D of the transistor device 844-1 is connected to the drain terminal D of the transistor device 844-N and the cascode device 834. A bias voltage V_{BG_BIASN_AMAM} for AM-AM compensation, which may be generated by the bias offer generator 208 depicted in FIG. 2, is applied to the back gates BG of the transistor devices 862-1, . . . , 862-M through the multiplexers 872-1, . . . , 872-M, while a bias voltage V_{BG_BIASP_AMAM} for AM-AM compensation, which may be generated by the bias offer generator 208 depicted in FIG. 2, is applied to the back gates BG of the transistor devices 864-1, . . . , 864-M through the multiplexers 874-1, . . . , 874-M. The gate terminal G of the transistor device 862-1 is connected to the gate terminal G of the transistor device 862-M and the input voltage Vᵢₙ₋, the source terminal S of the transistor device 862-1 is connected to the source terminal S of the transistor device 862-M, and the drain terminal D of the transistor device 862-1 is connected to the drain terminal D of the transistor device 862-M and the cascode device 832. The gate terminal G of the transistor device 864-1 is connected to the gate terminal G of the transistor device 864-N and the input voltage Vᵢₙ₊, the source terminal S of the transistor device 864-1 is connected to the source terminal S of the transistor device 864-M, and the drain terminal D of the transistor device 864-1 is connected to the drain terminal D of the transistor device 864-M and the cascode device 834. In the embodiment depicted in FIG. 8, segmentation on BG bias voltages V_{BG_BIASN_HD2}, V_{BG_BIASP_HD2} are used to adjust HD2 (differential Mode) and segmentation on BG bias voltages V_{BG_BIASN_AMAM}, V_{BG_BIASP_AMAM} are used to adjust AM-AM (CM).

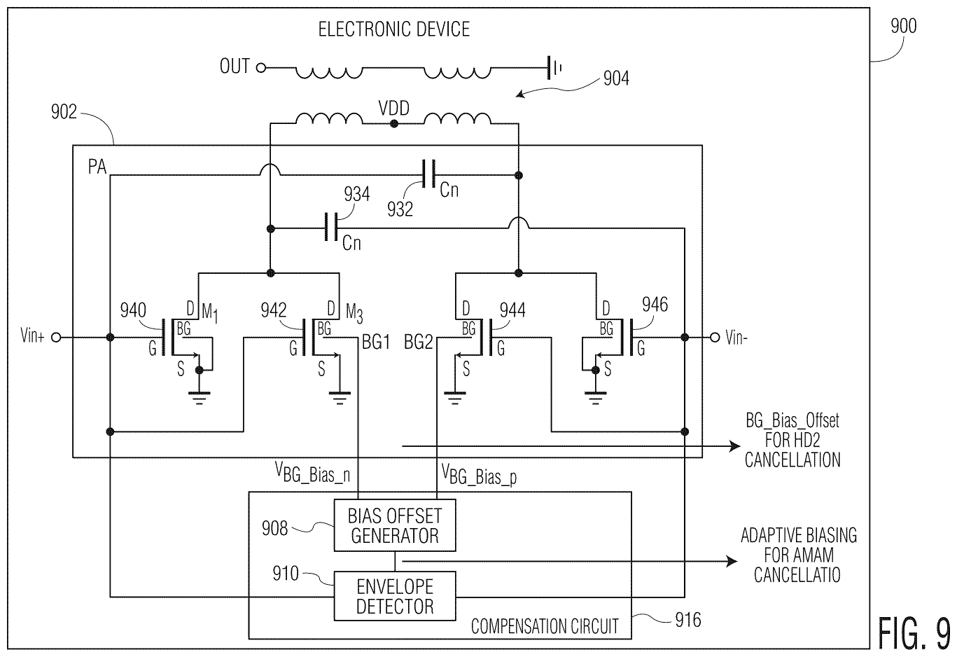

FIG. 9 depicts an electronic device 900 in accordance with an embodiment of the invention. The electronic device 900 can be used for Mm-wave PA with adaptive biasing and BG Offset for HD2 and AM-AM cancelation. The electronic device 900 depicted in FIG. 9 is an embodiment of the electronic device 100 depicted in FIG. 1. However, the electronic device 100 depicted in FIG. 1 is not limited to the embodiment depicted in FIG. 9. In the embodiment depicted in FIG. 9, the electronic device 900 includes a power amplifier (PA) 902 that is a Millimeter wave (mmWave) PA, a transformer 904, and a compensation circuit 916 that includes a bias offset generator 908 and an envelope detector 910. The PA 902 may include N segments of PA gm input devices with BG bias inputs, where N is a positive integer that is larger than one. The PA 902, the transformer 904, the bias offset generator 908, and the envelope detector 910 depicted in FIG. 9 are embodiments of the PA 102, the transformer 104, the antenna 106, the bias offset generator 108, and the envelope detector 110 depicted in FIG. 1. However, the PA 102, the transformer 104, the bias offset generator 108, and the envelope detector 110 depicted in FIG. 1 are not limited to the embodiments depicted in FIG. 9. In some embodiments, the electronic device 900 is a transmitter circuit, for example, a wireless transmitter circuit. Although the depicted electronic device 900 is shown in FIG. 9 with certain components and described with certain functionality herein, other embodiments of the electronic device 900 may include fewer or more components to implement the same, less, or more functionality. For example, the electronic device 900 may include an antenna operably connected to the transformer 904. In addition, although the electronic device 900 is shown in FIG. 9 as being connected in a certain topology, the network topology of the electronic device 900 is not limited to the topology shown in FIG. 9.

In the embodiment depicted in FIG. 9, the transformer 904 is operably connected to the PA 902 and may be operably connected to an antenna (not shown in FIG. 9). The transformer 904 may be connected to a fixed voltage, such as the ground (zero volt). In some embodiments, the transformer 904 is a Balun transformer.

The compensation circuit 916 depicted in FIG. 9 may be the same as or similar to the compensation circuit 216 depicted in FIG. 2. However, the compensation circuit 916 depicted in FIG. 9 is not limited to the embodiment depicted in FIG. 2. In the embodiment depicted in FIG. 9, the bias offset generator 908 is configured to generate bias voltages V_{BG_Bias_P}, V_{BG_Bias_N} that are applied to the PA 902. The bias offset generator 908 depicted in FIG. 9 may be the same as or similar to the bias offset generator 208 depicted in FIG. 2. However, the bias offset generator 908 depicted in FIG. 9 is not limited to the embodiment depicted in FIG. 2. In the embodiment depicted in FIG. 9, the envelope detector 910 is configured to perform envelope detection. The envelope detector 910 depicted in FIG. 9 may be the same as or similar to the envelope detector 210 depicted in FIG. 2. However, the envelope detector 910 depicted in FIG. 9 is not limited to the embodiment depicted in FIG. 2.

In the embodiment depicted in FIG. 9, the PA 902 includes two capacitors 932, 934 and four transistor devices 940 (M₁), 942 (M₃), 944 (M₄), 946 (M₂), which are NMOS devices with back gates BG. Specifically, static back gate bias are applied to the transistor devices M₁ and M₂, while adaptive biasing and HD2 cancelation are applied through back gates BG1, BG2 of the transistor devices M₃ and M₄. In the embodiment depicted in FIG. 9, the bias voltage V_{BG_Bias_N}, which is generated by the bias offer generator 908 depicted in FIG. 9, is applied to the back gate BG of the transistor device 942 (also referred to as M₃), while the bias voltage V_{BG_Bias_P}, which is generated by the bias offer generator 908 depicted in FIG. 9, is applied to the back gate BG of the transistor device 944 (also referred to as M₄). The gate terminal G of the transistor device 942 is connected to the gate terminal G of the transistor device 940 (also referred to as M₁) and to an input voltage Vᵢₙ₊, the source terminal S of the transistor device 942 and the source terminal S of the transistor device 940 are connected to a fixed voltage, for example, the ground, and the drain terminal D of the transistor device 942 is connected to the drain terminal D of the transistor device 940 and the capacitor 932. The gate terminal G of the transistor device 944 is connected to the gate terminal G of the transistor device 946 (also referred to as M₂) and to an input voltage Vᵢₙ₋, the source terminal S of the transistor device 944 and the source terminal S of the transistor device 946 are connected to a fixed voltage, for example, the ground, and the drain terminal D of the transistor device 944 is connected to the drain terminal D of the transistor device 946 and the capacitor 934. In the embodiment depicted in FIG. 9, BG bias voltages V_{BG_Bias_P}, V_{BG_Bias_N} are used to adjust both HD2 (differential Mode) and AM-AM (CM).

In the embodiment depicted in FIG. 9, the bias offset generator 908 and the envelope detector 910 are used for on-chip HD2 and AM-AM distortion compensation. Using the bias offset generator 908 and the envelope detector 910, the systemic offset of the PA 902, such as routing, balun and devices mismatch, can be effectively canceled out by adjusting offset voltages between the back gates BG1, BG2 of the transistor devices 942, 944 in the PA 902. In addition, the AM-AM distortion is compensated with adaptive biasing through the back gates BG1, BG2 of the transistor devices 942, 944 in the PA 902. Subsequently, the corresponding limitation of the HD2 emission and AM-AM distortion in the electronic device 900 can be eliminated, which enables the possibility of the high-power transmitters without violating the spectrum mask due to out-of-band HD2 emission and compensating AM-AM cancelation at the same time through the back gates BG1, BG2 of the transistor devices 942, 944 in the PA 902. The bias offset generator 908 and/or the envelope detector 910 may be fully or partially implemented as an IC device. In some embodiments, the bias offset generator 908 and the envelope detector 910 are located in the same substrate and are implemented as one IC device (e.g., a system on chip (SOC)). In some embodiments, the bias offset generator 908 and the envelope detector 910 are located in separate substrates and are implemented as separate IC devices.

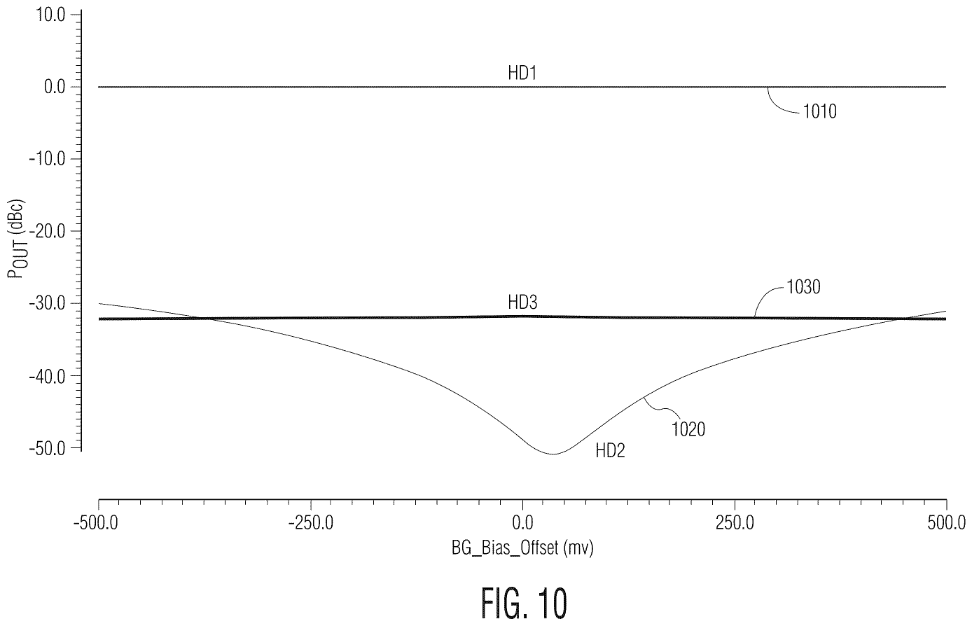

FIG. 10 depicts a plot of PA output power versus BG bias offset of the electronic device 900 depicted in FIG. 9. As depicted in FIG. 10, the curve 1010 represents first harmonic (HD1), the curve 1020 represents second harmonic (HD2), and the curve 1030 represents third harmonic (HD3). As depicted in FIG. 10, HD2 reduction or cancelation can be achieved using static BG bias offset.

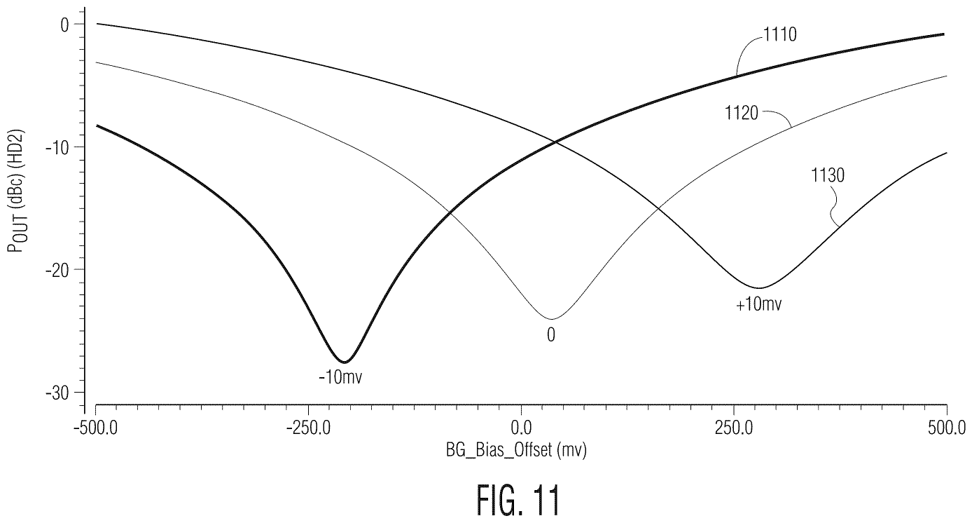

FIG. 11 depicts a plot of PA output power versus BG bias offset under different gate-drain voltage Vas of the electronic device 900 depicted in FIG. 9. As depicted in FIG. 11, the curve 1110 represents VGs of −10 mv, the curve 1120 represents VGs of 0 mv, and the curve 1130 represents VGs of 10 mv.

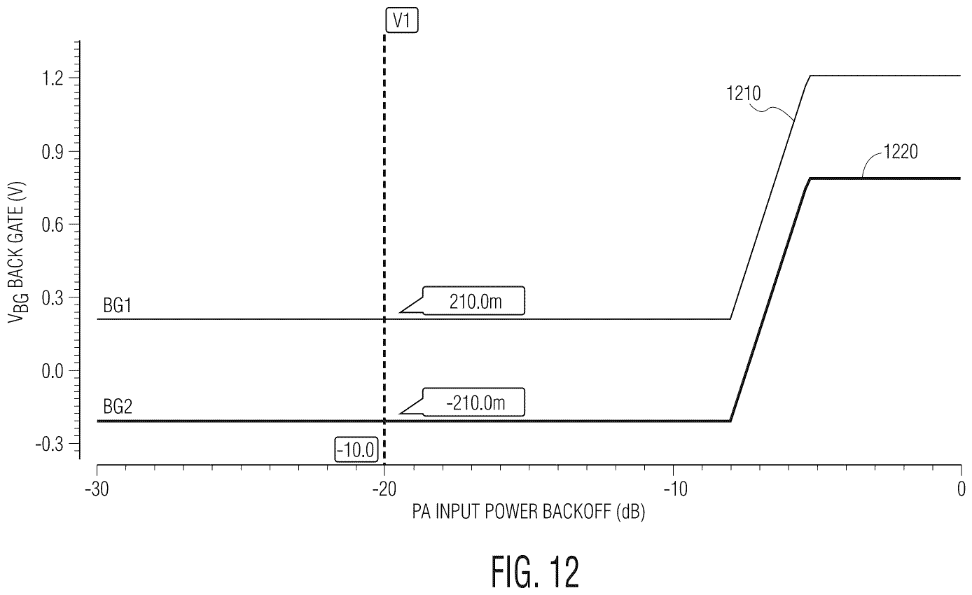

FIG. 12 depicts a plot of bias voltage versus PA input power (back off) of the electronic device 900 depicted in FIG. 9. As depicted in FIG. 12, the curve 1210 represents the bias voltage applied to the back gate BG1 of the transistor device 942 (M₃), while the curve 1220 represents the bias voltage applied to the back gate BG2 of the transistor device 944 (M₄).

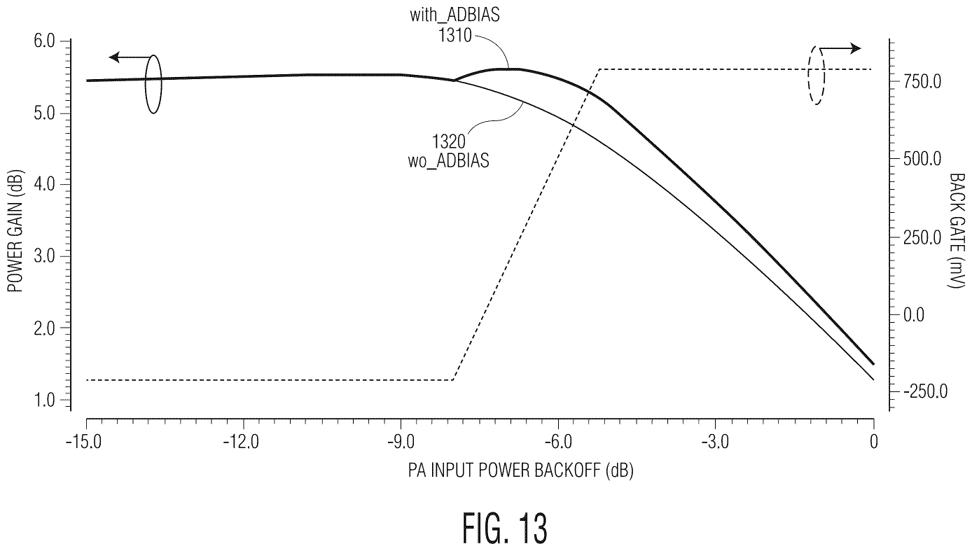

FIG. 13 depicts a plot of PA gain versus PA input power (back off) of the electronic device 900 depicted in FIG. 9. As depicted in FIG. 13, the curve 1310 represents PA gain with BG adaptive Bias, while the curve 1320 represents PA gain without BG adaptive Bias.

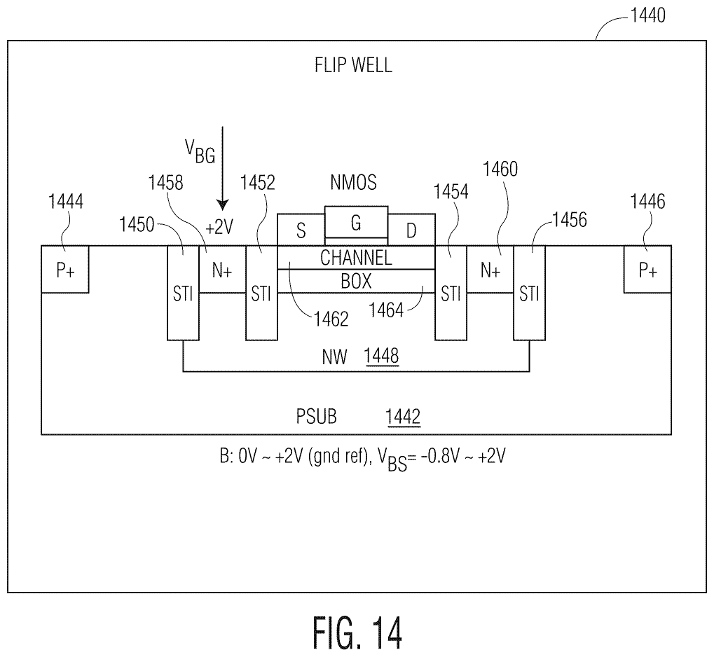

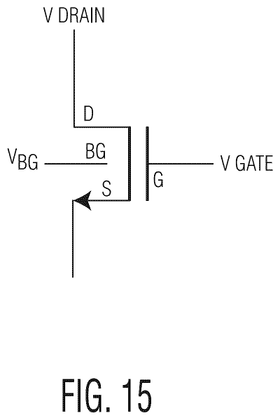

FIG. 14 depicts a transistor device 1440 in accordance with an embodiment of the invention. In the embodiment depicted in FIG. 14, the transistor device 1440 is a flip-well NMOS transistor with a back gate BG. The transistor device 1440 depicted in FIG. 14 is an embodiment of the transistor devices 640, 642, 644, 646 depicted in FIG. 6, the transistor devices 742-1, . . . , 742-N, 744-1, . . . , 744-N depicted in FIG. 7, the transistor devices 842-1, . . . , 742-N, 844-1, . . . , 844-N, 862-1, . . . , 862-M, 864-1, . . . , 864-M depicted in FIG. 8, and/or the transistor devices 940, 942, 944, 946 depicted in FIG. 9. However, the transistor devices 640, 642, 644, 646 depicted in FIG. 6, the transistor devices 742-1, . . . , 742-N, 744-1, . . . , 744-N depicted in FIG. 7, the transistor devices 842-1, . . . , 742-N, 844-1, . . . , 844-N, 862-1, . . . , 862-M, 864-1, . . . , 864-M depicted in FIG. 8, and/or the transistor devices 940, 942, 944, 946 depicted in FIG. 9 are not limited to the embodiment depicted in FIG. 14. In the embodiment depicted in FIG. 14, the transistor device 1440 includes a P-type substrate (PSUB) layer 1442. Two P+ regions 1444, 1446 and a N-well (NW) region 1448 are formed in the PSUB layer 1442. Four shallow trench isolation (STI) regions 1450, 1452, 1454, 1456 are formed in the PSUB layer 1442 and/or the NW region 1448. In addition, two N+ regions 1458, 1460, a channel region 1462, and a box region 1464 are formed in the NW region 1448. Source(S), gate (G), and drain (D) nodes/terminals are formed on top of the channel region 1462. The N+ region 1458 can form a back gate, to which a back gate voltage V_{BG} is applied. FIG. 15 depicts a schematic diagram of the transistor device 1440 depicted in FIG. 14. As depicted in the schematic diagram of FIG. 15, the transistor device 1440 has a gate terminal (G) to which a voltage V_{gate} is applied, a drain terminal (D) to which a voltage V_{drain} is applied, a source terminal(S) to which a voltage V_{source} is applied, and a back gate terminal (BG) to which a voltage V_{BG} is applied.

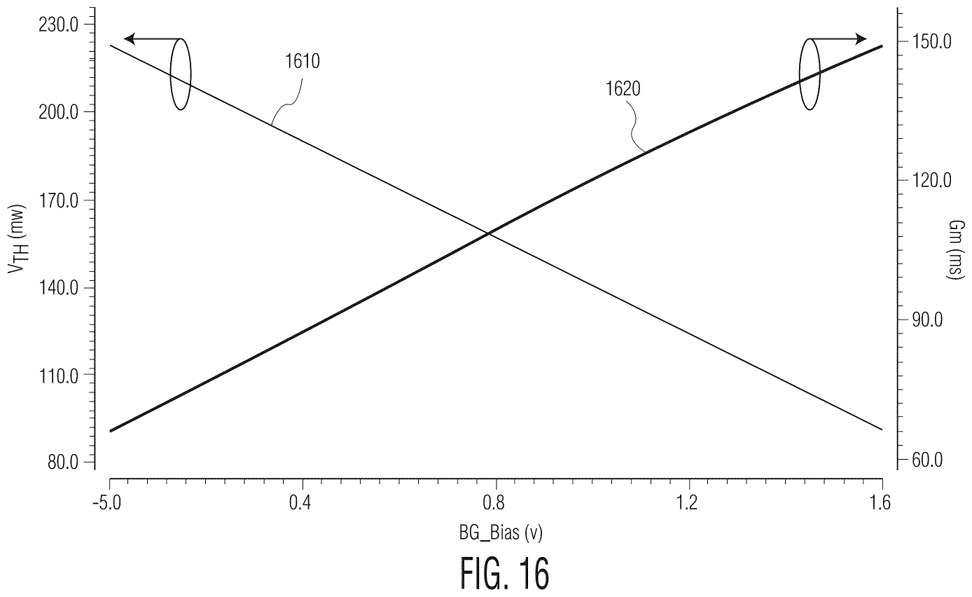

FIG. 16 depicts a plot of the threshold voltage VTH and transconductance (Gm) of the transistor device 1440 depicted in FIG. 14 versus the back gate bias voltage of the transistor device 1440 depicted in FIG. 14. As depicted in FIG. 16, the curve 1610 represents the threshold voltage VTH, while the curve 1620 represents Gm values. The threshold voltage VTH is reduced by increasing the back gate voltage, which results in a larger Gm.

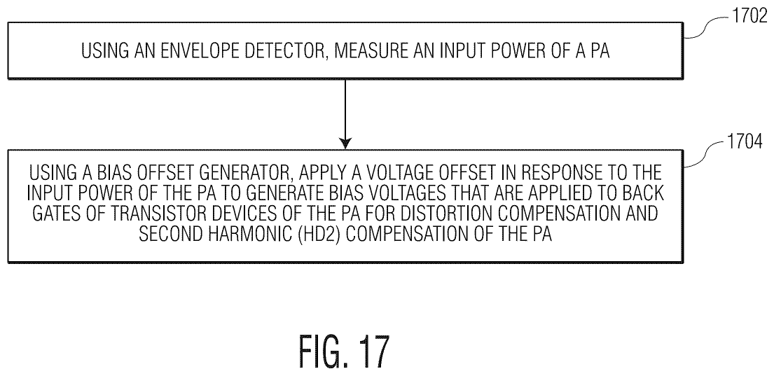

FIG. 17 is a process flow diagram of a method for power amplifier (PA) compensation in accordance with an embodiment of the invention. At block 1702, using an envelope detector, an input power of a PA is measured. At block 1702, using a bias offset generator, a voltage offset is applied in response to the input power of the PA to generate bias voltages that are applied to back gates of transistor devices of the PA for distortion compensation and second harmonic (HD2) compensation of the PA. In some embodiments, using the envelope detector, a bias voltage is generated, and using the bias offset generator, the voltage offset is applied to the bias voltage to generate a differential pair of bias voltages. The envelope detector may be the same as or similar to the envelope detector 110 depicted in FIG. 1, the envelope detector 210 depicted in FIG. 2, and/or the envelope detector 910 depicted in FIG. 9. The bias offset generator may be the same as or similar to the bias offset generator 108 depicted in FIG. 1, the bias offset generator 208 depicted in FIG. 2, and/or the bias offset generator 908 depicted in FIG. 9. The PA may be the same as or similar to the PA 102 depicted in FIG. 1, the PA 202 depicted in FIG. 2, the PA 602 depicted in FIG. 6, the PA 702 depicted in FIG. 7, the PA 802 depicted in FIG. 8, and/or the PA 902 depicted in FIG. 9.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

Although the operations of the method(s) herein are shown and described in a particular order, the order of the operations of each method may be altered so that certain operations may be performed in an inverse order or so that certain operations may be performed, at least in part, concurrently with other operations. In another embodiment, instructions or sub-operations of distinct operations may be implemented in an intermittent and/or alternating manner.

It should also be noted that at least some of the operations for the methods described herein may be implemented using software instructions stored on a computer useable storage medium for execution by a computer. As an example, an embodiment of a computer program product includes a computer useable storage medium to store a computer readable program.

The computer-useable or computer-readable storage medium can be an electronic, magnetic, optical, electromagnetic, infrared, or semiconductor system (or apparatus or device). Examples of non-transitory computer-useable and computer-readable storage media include a semiconductor or solid-state memory, magnetic tape, a removable computer diskette, a random-access memory (RAM), a read-only memory (ROM), a rigid magnetic disk, and an optical disk. Current examples of optical disks include a compact disk with read only memory (CD-ROM), a compact disk with read/write (CD-R/W), and a digital video disk (DVD).

Alternatively, embodiments of the invention may be implemented entirely in hardware or in an implementation containing both hardware and software elements. In embodiments which use software, the software may include but is not limited to firmware, resident software, microcode, etc.

Although specific embodiments of the invention have been described and illustrated, the invention is not to be limited to the specific forms or arrangements of parts so described and illustrated. The scope of the invention is to be defined by the claims appended hereto and their equivalents.

What is claimed is:

1. A compensation circuit for a power amplifier (PA), the compensation circuit comprising:
an envelope detector configured to measure an input power of the PA; and
a bias offset generator configured to apply a voltage offset in response to the input power of the PA to generate a plurality of bias voltages that are applied to a plurality of back gates of a plurality of transistor devices of the PA for distortion compensation and second harmonic (HD2) compensation of the PA.

2. The compensation circuit of claim 1, wherein the envelope detector is further configured to measure the input power of the PA to generate a bias voltage, and wherein the bias offset generator is further configured to apply the voltage offset to the bias voltage to generate a differential pair of bias voltages.

3. The compensation circuit of claim 1, wherein the envelope detector is operably connected to a plurality of input terminals of the PA to sense an input voltage of the PA.

4. The compensation circuit of claim 1, wherein the envelope detector comprises a first passive mixer with a first gain and a second passive mixer with a second gain.

5. The compensation circuit of claim 4, wherein the envelope detector further comprises a transimpedance amplifier (TIA) configured to convert a sum of a plurality of output currents of the first and second passive mixers into an output voltage.

6. The compensation circuit of claim 5, wherein the bias offset generator comprises a voltage adder circuit configured to add the voltage offset to the output voltage to generate a first bias voltage and a voltage subtractor circuit configured to subtract the voltage offset from the output voltage to generate a second bias voltage.

7. The compensation circuit of claim 1, wherein the PA comprises a sub-6 gigahertz (GHz) PA.

8. The compensation circuit of claim 7, wherein the sub-6 GHZ PA comprises a plurality of cascode devices and a plurality of transistor devices with a plurality of back gates operably connected to the cascode devices.

9. The compensation circuit of claim 8, wherein the transistor devices with the back gates comprise a plurality of segments of transistor devices and a plurality of multiplexers.

10. The compensation circuit of claim 1, wherein the PA comprises a millimeter wave (mmWave) PA.

11. The compensation circuit of claim 10, wherein the mm Wave PA comprises a plurality of capacitors and a plurality of transistor devices with a plurality of back gates operably connected to the capacitors.

12. A compensation circuit for a sub-6 gigahertz (GHz) power amplifier (PA), the compensation circuit comprising:
an envelope detector configured to measure an input power of the PA to generate a bias voltage; and
a bias offset generator configured to apply a voltage offset to the bias voltage to generate a differential pair of bias voltages that is applied to a plurality of back gates of a plurality of transistor devices of the PA for distortion compensation and second harmonic (HD2) compensation of the PA.

13. The compensation circuit of claim 12, wherein the sub-6 GHz PA comprises a plurality of cascode devices and a plurality of transistor devices with a plurality of back gates operably connected to the cascode devices.

14. The compensation circuit of claim 13, wherein the transistor devices with the back gates comprise a plurality of segments of transistor devices and a plurality of multiplexers.

15. The compensation circuit of claim 12, wherein the envelope detector is operably connected to a plurality of input terminals of the sub-6 GHZ PA to sense an input voltage of the sub-6 GHZ PA.

16. The compensation circuit of claim 12, wherein the envelope detector comprises a first passive mixer with a first gain and a second passive mixer with a second gain.

17. The compensation circuit of claim 16, wherein the envelope detector further comprises a transimpedance amplifier (TIA) configured to convert a sum of a plurality of output currents of the first and second passive mixers into an output voltage.

18. The compensation circuit of claim 17, wherein the bias offset generator comprises a voltage adder circuit configured to add the voltage offset to the output voltage to generate a first bias voltage and a voltage subtractor circuit configured to subtract the voltage offset from the output voltage to generate a second bias voltage.

19. A method for power amplifier (PA) compensation, the method comprising:
using an envelope detector, measuring an input power of a PA; and
using a bias offset generator, applying a voltage offset in response to the input power of the PA to generate a plurality of bias voltages that are applied to a plurality of back gates of a plurality of transistor devices of the PA for distortion compensation and second harmonic (HD2) compensation of the PA.

20. The method of claim 19, wherein using the envelope detector, measuring the input power of the PA comprises using the envelope detector, measuring the input power of the PA to generate a bias voltage, and wherein using the bias offset generator, applying the voltage offset in response to the input power of the PA to generate the bias voltages comprises using the bias offset generator, applying the voltage offset to the bias voltage to generate a differential pair of bias voltages.
